(19) United States
(12) Patent Application Publication
(10) Pub. No.: US 2025/0006618 A1
(43) Pub. Date: Jan. 2, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/634,101

(22) Filed: Apr. 12, 2024

(30) Foreign Application Priority Data
Jun. 27, 2023 (KR) 10-2023-0082885

(51) Int. Cl. H01L 23/498; H01L 23/00; H01L 23/48; H01L 25/18

(52) U.S. Cl. CPC H01L 23/49838; H01L 23/49816; H01L 23/49833; H01L 24/05; H01L 24/06; H01L 24/08; H01L 24/16; H01L 25/18; H01L 23/481; H01L 2224/05005; H01L 2224/05015; H01L 2224/06137; H01L 2224/08225; H01L 2224/16238; H01L 2225/06517; H01L 2924/1431; H01L 2924/1436

(57) ABSTRACT

Provided is a semiconductor package including a package substrate, a redistribution structure including a single-layered insulating layer positioned above the package substrate, and a plurality of horizontal redistribution structures embedded in the insulating layer and arranged side-by-side in a first horizontal direction parallel to an upper surface of the package substrate and in a second horizontal direction perpendicular to the first horizontal direction, external connection terminals arranged below the redistribution structure, and a semiconductor chip provided on the redistribution structure and including a chip body and chip connection terminals arranged below the chip body, wherein each of the plurality of horizontal redistribution structures includes a via passing through the insulating layer, and a tracer pattern formed integrally with the via and inclined and long from the first horizontal direction and the second horizontal direction.

### CROSS-REFERENCE TO RELATED APPLICATION

This application is based on and claims priority under 35 U.S.C. § 119 to Korean Patent Application No. 10-2023-0082885, filed on Jun. 27, 2023, in the Korean Intellectual Property Office, the disclosure of which is incorporated by reference herein in its entirety.

### BACKGROUND

Embodiments of the disclosure relate to a semiconductor package, and more particularly, to a semiconductor package including a redistribution structure.

With the development of the electronics industry and the needs of users, electronic devices have become smaller and lighter. As electronic devices are made smaller and lighter, semiconductor packages used for the electronic devices also have to become smaller and lighter, while having high reliability, high performance and large capacity. Moreover, when semiconductor packages have high performance and high capacity, power consumption of the semiconductor packages also increases. Accordingly, there is an increase need for semiconductor packages having a structure for responding to the size and performance of the semiconductor packages and stably supplying power to the semiconductor packages.

### SUMMARY

Aspects of the disclosure provide a semiconductor package capable of reducing process costs and easily controlling warpage.

According to an aspect of the disclosure, there is provide a semiconductor package including: a package substrate; a redistribution structure including: an insulating layer provided on a first side of the package substrate, and a plurality of horizontal redistribution structures provided in the insulating layer and arranged adjacent to each other in a first horizontal direction and a second horizontal direction, the first and the second horizontal directions parallel to an upper surface of the package substrate and the second horizontal direction perpendicular to the first horizontal direction; external connection terminals provided on a first side of the redistribution structure; and a semiconductor chip provided on the redistribution structure, the semiconductor chip including a chip body and chip connection terminals provided on a first side of the chip body; wherein each of the plurality of horizontal redistribution structures includes: a via through the insulating layer; a tracer pattern formed integrally with the via and extending at an angle from the first horizontal direction and the second horizontal direction; a first bonding pad provided on the insulating layer, integrally formed with the via, and formed at a first position on the tracer pattern; and a second bonding pad formed at a second position on the tracer pattern different from the first position and bonded to the chip connection terminal.

According to another aspect of the disclosure, there is provided a semiconductor package including: a package substrate; a redistribution structure including: an insulating layer provided on a first side of the package substrate, a plurality of horizontal redistribution structures provided in the insulating layer and arranged adjacent to each other in a first horizontal direction and in a second horizontal direction perpendicular to the first horizontal direction, and a plurality of vertical redistribution structures; external connection terminals provided on a first side of the redistribution structure; a first semiconductor chip provided on the redistribution structure, the semiconductor chip including a first chip body and first chip connection terminals provided on a first side of the first chip body; and a second semiconductor chip spaced apart from the first semiconductor chip in the first horizontal direction and including a second chip body and second chip connection terminals provided on a first side of the second chip body; wherein the plurality of vertical redistribution structures completely overlap the first semiconductor chip in a vertical direction, wherein each of the plurality of horizontal redistribution structures includes: a via through the insulating layer; a tracer pattern formed integrally with the via and extending at an angle from the first horizontal direction and the second horizontal direction; a first bonding pad provided on the insulating layer, integrally formed with the via, and formed at a first position on the tracer pattern; and a second bonding pad formed at a second position on the tracer pattern different from the first position and bonded to the second chip connection terminal.

According to another aspect of the disclosure, there is provided a semiconductor package including a package substrate; a redistribution structure including: an insulating layer provided on a first side the package substrate, a plurality of horizontal redistribution structures provided in the insulating layer and arranged side-by-side in a first horizontal direction and in a second horizontal direction perpendicular to the first horizontal direction, and a plurality of vertical redistribution structures; external connection terminals arranged below the redistribution structure; a first semiconductor chip provided on the redistribution structure, the semiconductor chip including a first chip body and first chip connection terminals arranged on a first side of the first chip body; and a second semiconductor chip spaced apart from the first semiconductor chip in the first horizontal direction and including a second chip body and second chip connection terminals arranged on a first side of the second chip body; wherein the plurality of horizontal redistribution structures further includes: a first horizontal redistribution structure overlapping a vertex of the second semiconductor chip in a plan view and extend in a first angle with respect to the second horizontal direction; a second horizontal redistribution structure spaced apart from the first horizontal redistribution structure in the first horizontal direction and extend in a second angle different from the first angle with respect to the second horizontal direction; and a third horizontal redistribution structure spaced apart from the first horizontal redistribution structure in the second horizontal direction and extend in a third angle different from the first angle with respect to the second horizontal direction, wherein the plurality of vertical redistribution structures completely overlap the first semiconductor chip in a vertical direction.

According to another aspect of the disclosure, there is provided a method of manufacturing a semiconductor package, the method including: forming an insulating layer on an adhesive film attached to a carrier substrate and patterning the insulating layer to form a plurality of holes; applying a seed layer on the plurality of holes; forming a plurality of reference patterns between the plurality of holes on the insulating layer; filling spaces between the plurality of reference patterns and the plurality of holes with metal material to form a plurality of horizontal redistribution structures and a plurality of vertical redistribution structures; and after removing the plurality of reference patterns, bonding first chip connection terminals of the first semiconductor chip to the plurality of vertical redistribution structures, and bonding second chip connection terminals of a second semiconductor chip to the plurality of horizontal redistribution structures; wherein each of the plurality of horizontal redistribution structures includes: a via through the insulating layer; a tracer pattern formed integrally with the via and extending at an angle from the first horizontal direction and the second horizontal direction; a first bonding pad provided on the insulating layer, integrally formed with the via, and formed at a first position on the tracer pattern; and a second bonding pad formed at a second position on the tracer pattern different from the first position and bonded to the chip connection terminal.

### BRIEF DESCRIPTION OF DRAWINGS

Embodiments will be more clearly understood from the following detailed description taken in conjunction with the accompanying drawings in which:

FIG. 1A is a plan view of a redistribution structure of a semiconductor package according to an embodiment;

FIG. 1B is an enlarged view of a portion P1 of FIG. 1A;

FIG. 1C is a cross-sectional view taken along a line A-A′ of FIG. 1A;

FIG. 1D is a cross-sectional view taken along a line B-B′ of FIG. 1A;

FIG. 2A is a plan view of a redistribution structure of a semiconductor package according to an embodiment;

FIG. 2B is an enlarged view of a portion P2 of FIG. 2A;

FIG. 2C is a cross-sectional view taken along a line C-C′ of FIG. 2A;

FIG. 3A is a plan view of a redistribution structure of a semiconductor package according to an embodiment;

FIG. 3B is an enlarged view of a portion P3 of FIG. 3A;

FIG. 3C is a cross-sectional view taken along a line D-D′ of FIG. 3A;

FIG. 4A is a plan view of a redistribution structure of a semiconductor package according to an embodiment;

FIG. 4B is a cross-sectional view taken along a line E-E′ of FIG. 4A;

FIGS. 5A and 5B are cross-sectional views of a semiconductor package according to an embodiment;

FIGS. 6A and 6B are cross-sectional views of a semiconductor package according to an embodiment; and

FIGS. 7 to 16 are cross-sectional views sequentially illustrating a method of manufacturing a semiconductor package, according to an embodiment.

### DETAILED DESCRIPTION

Hereinafter, embodiments will be described in detail with reference to the accompanying drawings.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

However, the disclosure does not have to be configured as limited to the embodiments described below and may be embodied in various other forms. The following embodiments are not provided to fully complete the disclosure, but rather to fully convey the scope of the disclosure to those skilled in the art.

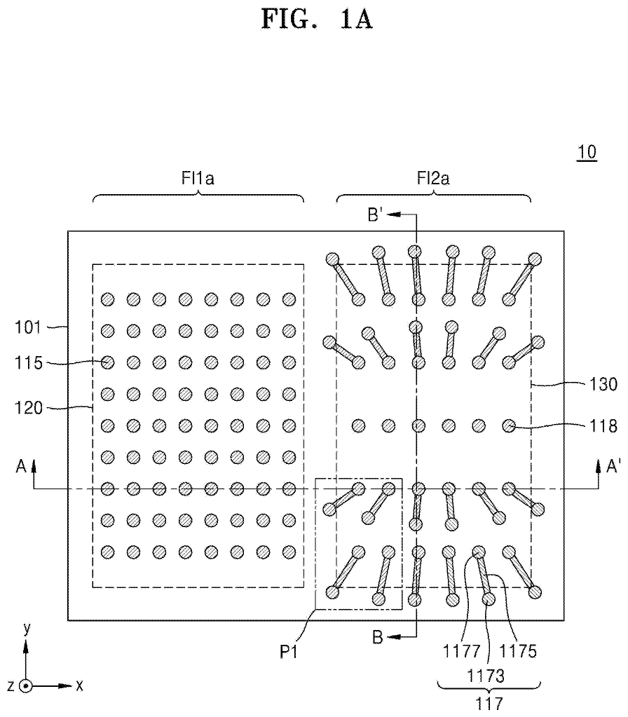

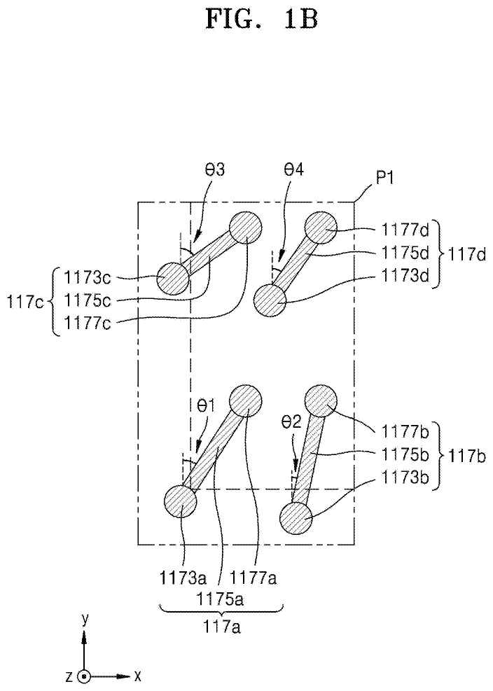

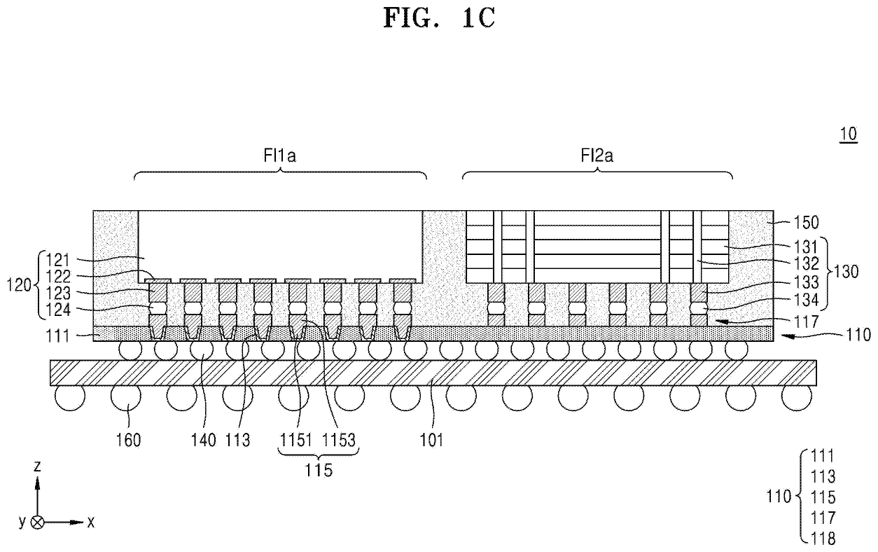

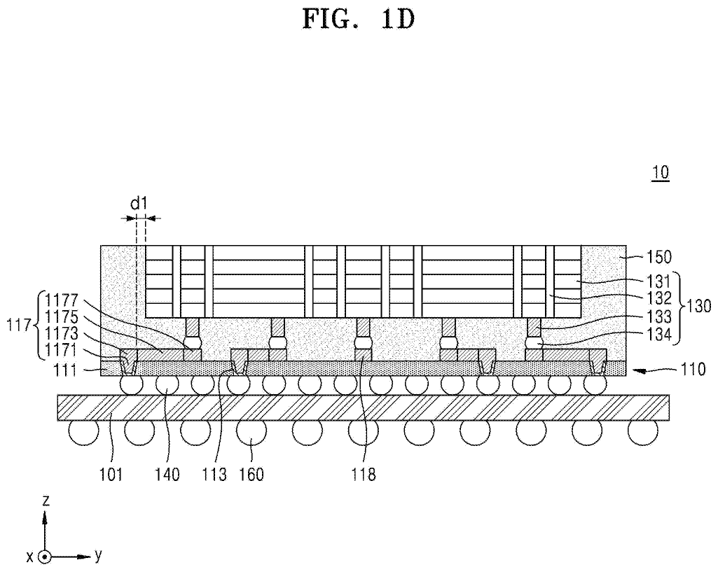

FIG. 1A is a plan view of a redistribution structure of a semiconductor package according to an embodiment, and FIG. 1B is an enlarged view of a portion P1 of FIG. 1A. FIG. 1C is a cross-sectional view taken along a line A-A′ of FIG. 1A, and FIG. 1D is a cross-sectional view taken along a line B-B′ of FIG. 1A.

Referring to FIGS. 1A to 1D, a semiconductor package 10 according to an embodiment may include a package substrate 101, a redistribution structure 110 positioned above the package substrate 101, a first semiconductor chip 120 provided on the redistribution structure 110, and a second semiconductor chip 130 provided on the redistribution structure 110. The second semiconductor chip 130 being spaced apart from the first semiconductor chip 120 in a first horizontal direction (X direction). The semiconductor package 10 may include a plurality of external connection terminals. The plurality of external connection terminals may include a plurality of first external connection terminals 140 provided on a lower surface of the redistribution structure 110, and a plurality of second external connection terminals 160 provided on a lower surface of the package substrate 101.

According to an embodiment, the package substrate 101 may be in the form of a flat plate or a panel. The package substrate 101 may include an upper surface and a lower surface opposite to the upper surface. Each of the upper and lower surfaces of the package substrate 101 may be flat. However, the disclosure is not limited thereto. Hereinafter, each of the first horizontal direction (X direction) and a second horizontal direction (Y direction) perpendicular to the first horizontal direction (X direction) may be defined as a direction parallel to the upper surface of the package substrate 101, and a vertical direction (Z direction) may be defined as a direction perpendicular to the upper surface of the package substrate 101. The package substrate 101 may include, but is not limited to, a printed circuit board (PCB).

The second external connection terminals 160 may be arranged on the lower surface of the package substrate 101. The second external connection terminals 160 may be configured to electrically and physically connect the package substrate 101 to an external device. The second external connection terminals 160 may have solder balls, conductive bumps or a flip-chip connection structure with a grid array such as a pin grid array, a ball grid array, or a land grid array. However, the disclosure is not limited thereto, and as such, the second external connection terminals 160 may include another type of connection.

According to an embodiment, the redistribution structure 110 may include an insulating layer 111, a plurality of vertical redistribution structures 115 provided in the insulating layer 111 and arranged side by side in the first horizontal direction (X direction) and the second horizontal direction (Y direction), a plurality of horizontal redistribution structures 117, and center redistribution structures 118 in the middle of the plurality of horizontal redistribution structures 117 arranged in the second horizontal direction (Y direction). According to an embodiment, the insulating layer 111 may be a single layer structure. For example, the insulating layer 111 may be a single-layer insulating layer. The plurality of vertical redistribution structures 115 may be embedded in the insulating layer 111. For example, the plurality of vertical redistribution structures 115 may be arranged adjacent to each other in the first horizontal direction (X direction) and the second horizontal direction (Y direction). According to an embodiment, a first fan-in area FI1a may be provided in a first area of the redistribution structure 110 and a second fan-in area FI2a may be provided in a second area of the redistribution structure 110. The first area and the second area may be adjacent to each other in the first horizontal direction (X direction) in a plan view. For example, as shown in FIG. 1A, one side of the redistribution structure 110 is a first fan-in area FI1a, and the other side opposite to the one side is a second fan-in area FI2a, the sides arranged in the first horizontal direction (X direction) in a plan view. In the first fan-in area FI1a of the redistribution structure 110, the plurality of vertical redistribution structures 115 may be arranged side-by-side in the first horizontal direction (X direction) and the second horizontal direction (Y direction), and in the second fan-in area FI2a of the redistribution structure 110, the plurality of horizontal redistribution structures 117 may be arranged side-by-side in the first horizontal direction (X direction) and the second horizontal direction (Y direction). Each of the plurality of horizontal redistribution structures 117 may include a horizontal redistribution via 1171, a tracer pattern 1175, a first bonding pad 1173 and a second bonding pad 1177. The horizontal redistribution via 1171 may pass through the insulating layer 111. The tracer pattern 1175 may be integrally formed with the horizontal redistribution via 1171 and extending at an angle with respect to the first horizontal direction (X direction) and the second horizontal direction (Y direction). The first bonding pad 1173 may be provided on the insulating layer 111, integrally formed with the horizontal redistribution via 1171, and formed at a first position on the tracer pattern 1175. The second bonding pad 1177 may be provided at a second position on the tracer pattern 1175, and connected to a second chip connection terminal 134. For example, the second bonding pad 1177 may be bonded to a second chip connection terminal 134. For example, the first bonding pad 1173 may be provided on one end of the tracer pattern 1175, and the second bonding pad 1177 may be provided on the other end (e.g., opposite to the one end) of the tracer pattern 1175. Each of a vertical level of an upper surface of the first bonding pad 1173 in the vertical direction (Z direction) and a vertical level of an upper surface of the second bonding pad 1177 in the vertical direction (Z direction) may be the same as a vertical level of an upper surface of the tracer pattern 1175 in the vertical direction (Z direction). In addition, as shown in FIG. 1D, the first bonding pad 1173 may be positioned farther from the center of the second semiconductor chip 130 than the second bonding pad 1177. A distance from an edge of the second semiconductor chip 130 to the first bonding pad 1173 of the horizontal redistribution structure 117 may be distance d1. In a plan view, the first bonding pad 1173 of the horizontal redistribution structure 117 may be outside the second semiconductor chip 130. As such, the second semiconductor chip 130 may not overlap the first bonding pad 1173 of the horizontal redistribution structure 117. The plurality of horizontal redistribution structures 117 and the plurality of vertical redistribution structures 115 are described in detail below.

According to an embodiment, the semiconductor package 10 may further include a seed layer 113 provided on a lower surface and side surfaces of each of vertical redistribution vias 1151 of the vertically redistribution structures 115, and a lower surface and side surfaces of each of the horizontal redistribution vias 1171 of the horizontal redistribution structures 117. For example, the seed layer is formed to cover the lower surface and the side surfaces of each of vertical redistribution vias 1151 of the vertically redistribution structures 115, and the lower surface and the side surfaces of each of the horizontal redistribution vias 1171 of the horizontal redistribution structures 117. For example, the seed layer conformally covers the lower surface and the side surfaces of each of vertical redistribution vias 1151 of the vertically redistribution structures 115, and the lower surface and the side surfaces of each of the horizontal redistribution vias 1171 of the horizontal redistribution structures 117. The seed layer 113 may include a titanium/copper (Ti/Cu) alloy and may prevent metal material of the vertical redistribution vias 1151 and metal material of the horizontal redistribution vias 1171 from diffusing into the insulating layer 111.

For example, the insulating layer 111 may include an insulating material which may include, but is not limited to, silicon oxide, silicon nitride, phosphosilicate glass (PSG), borophosphosilicate glass (BPSG), fluorosilicate glass (FSG), or a combination thereof.

According to an embodiment, the first semiconductor chip 120 may be positioned in the first fan-in area FI1a on the redistribution structure 110. The first semiconductor chip 120 may include a first chip body 121, first chip pads 122, first vertical connection conductors 123, and first chip connection terminals 124.

The first chip body 121 may include an integrated circuit. The integrated circuit may be any kind of integrated circuit including a memory circuit, a logic circuit, or a combination thereof. The memory circuit may include, but is not limited to, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. The logic circuit may include, but is not limited to, a central processing unit (CPU) circuit, a graphics processing unit (GPU) circuit, a controller circuit, an application specific integrated circuit (ASIC) circuit, an application processor (AP) circuit, or a combination thereof.

The integrated circuit may include a substrate. The substrate may include a semiconductor material, such as a group IV semiconductor material. a group III-V semiconductor material, a group II-VI semiconductor material, or a combination thereof. The group IV semiconductor material may include, but is not limited to, silicon (Si), germanium (Ge), or a combination thereof. The group III-V semiconductor material may include, but is not limited to, gallium arsenide (GaAs), indium phosphide (InP), gallium phosphide (GaP), indium arsenide (InAs), indium antimony (InSb), indium gallium arsenide (InGaAs), or a combination thereof. The Group II-VI semiconductor material may include, but is not limited to, zinc telluride (ZnTe), cadmium sulfide (CdS), or a combination thereof.

The first chip pads 122 may be provided on a lower surface of the first chip body 121 along the lower surface of the first chip body 121. The first chip pads 122 may provide connection between the first chip body 121 and the first vertical connection conductors 123. The first chip pads 122 may include a conductive material including, but not limited to, Cu, aluminum (Al), silver (Ag), gold (Au), tungsten (W), Ti, or a combination thereof.

The first vertical connection conductors 123 may be arranged between the first chip pads 122 and the first chip connection terminals 124. An upper surface of the first vertical connection conductor 123 may be connected to the first chip pad 122, and a lower surface of the first vertical connection conductor 123 may be connected to the first chip connecting terminal 124. For example, the upper surface of the first vertical connection conductor 123 may be physically connected or bonded to the first chip pad 122, and the lower surface of the first vertical connection conductor 123 may be physically connected or bonded to the first chip connecting terminal 124. The first vertical connection conductors 123 may include, for example, a conductive material, such as Cu, Al, Ag, Au, W, Ti, or a combination thereof. The first chip connection terminals 124 may be used to enable self-alignment between the first vertical connection conductors 123 and vertical redistribution pads 1153. The first chip connection terminals 124 may be bonded to the first vertical connection conductors 123 and the vertical redistribution pads 1153 in a molten state, where lines passing through the centers of the first vertical connection conductors 123 may not overlap lines passing through the centers of the corresponding vertical redistribution pads 1153, respectively. However, in the process of solidifying the first chip connection terminals 124 in the molten state, due to the surface tension of the first chip connection terminals 124, the lines passing through the centers of the vertical redistribution pads 1153 may overlap the lines passing through the centers of the first vertical connection conductors 123, respectively. That is, the first chip connection terminals 124 may align the vertical connection conductors 123 so that the centers of the first vertical connection conductors 123 and the centers of the first vertical redistribution pads 1153 coincide without error.

According to an embodiment, the second semiconductor chip 130 may be positioned in the second fan-in area FI2a on the redistribution structure 110. The second semiconductor chip 130 may include a plurality of stacked chips 131, through silicon vias 132, second vertical connection conductors 133, and second chip connection terminals 134. That is, the second semiconductor chip 130 may include high bandwidth memory (HBM).

The plurality of chips 131 may be connected to each other through the through silicon vias 132. The through silicon vias 132 may pass through each of the plurality of chips 131. The through silicon vias 132 may include at least one of metal or metal nitride. For example, the through silicon vias 132 may include at least one of Ti, tantalum (Ta), Al, Au, Cu, nickel (Ni), W, titanium nitride (TiN), or tantalum nitride (TaN). However, the disclosure is not limited thereto, and as such, through silicon vias 132 may include other material. Each of the plurality of chips 131 may include a logic semiconductor chip or a memory semiconductor chip. However, all of the plurality of chips 131 need not be of the same type. For example, a lowermost chip among the plurality of chips 131 may be a logic semiconductor chip and the other chips may be memory semiconductor chips. The logic semiconductor chip may include, but is not limited to, an AP, a CPU, or a controller. The memory chip may include, but is not limited to, DRAM, SRAM, PRAM, MRAM, RRAM, flash memory, or EEPROM.

The second vertical connection conductors 133 may be arranged between the lowermost chip among the plurality of chips 131 and the second chip connection terminals 134. A lower surface of the second vertical connection conductor 133 is bonded to the second chip connection terminal 134. The second vertical connection conductors 133 may include, but is not limited to, a conductive material including Cu, Al, Ag, Au, W, Ti, or a combination thereof.

According to an embodiment, the semiconductor package 10 may include a molding layer 150 on the insulating layer 111 to seal the first semiconductor chip 120, the second semiconductor chip 130, the plurality of vertical redistribution structures 115, and the plurality of horizontal redistribution structures 117. According to an embodiment, the molding layer 150 may be provided on side surfaces of the vertical redistribution pads 1153, a side surface of the tracer pattern 1175, and an upper surface and a side surface of the first bonding pad 1173. For example, the molding layer 150 may cover the side surfaces of the vertical redistribution pads 1153, the side surface of the tracer pattern 1175, the upper surface and the side surface of the first bonding pad 1173. The molding layer 150 may include, but is not limited to, a thermosetting resin, a thermoplastic resin, a UV curable resin, or a combination thereof. The molding layer 150 may include, but is not limited to, an epoxy resin, a silicone resin, or a combination thereof. The molding layer 150 may include, but is not limited to, an epoxy mold compound (EMC).

As shown in FIGS. 1A and 1B, the plurality of horizontal redistribution structures 117 may be arranged symmetrically with respect to a centerline crossing the center of the second semiconductor chip 130 in the first horizontal direction (X direction) and a centerline crossing the center of the second semiconductor chip 130 in the second horizontal direction (Y direction). As shown in FIGS. 1A and 1B, the plurality of horizontal redistribution structures 117 may include a first horizontal redistribution structure 117a, a second horizontal redistribution structure 117b spaced apart from the first horizontal redistribution structure 117a in the first horizontal direction (X direction), a third horizontal redistribution structure 117c spaced apart from the first horizontal redistribution structure 117a in the second horizontal direction (Y direction), and a fourth horizontal redistribution structure 117d spaced apart from the third horizontal redistribution structure 117c in the first horizontal direction (X direction). In addition, the fourth horizontal redistribution structure 117d may be spaced apart from the second horizontal redistribution structure 117b in the second horizontal direction (Y direction). The first horizontal redistribution structure 117a and the second horizontal redistribution structure 117b may be arranged on one side with respect to a centerline crossing the center of the second semiconductor chip 130 in the second horizontal direction (Y direction).

According to an embodiment, a first angle θ1 of the first horizontal redistribution structure 117a inclined with respect to the second horizontal direction (Y direction) may be different from a second angle θ2 of the second horizontal redistribution structure 117b inclined with respect to the second horizontal direction (Y direction). As shown in FIG. 1B, since the first horizontal redistribution structure 117a is positioned further outside the second semiconductor chip 130 in a plan view than the second horizontal redistribution structure 117b, the first angle θ1 may be greater than the second angle θ2. However, the first angle θ1 is not necessarily limited thereto, and as such, according to another embodiment, the first angle θ1 may be less than the second angle θ2.

The first horizontal redistribution structure 117a includes a first tracer pattern 1175a extending at the first angle 01 from the second horizontal direction (Y direction), a first bonding pad 1173a which is formed at one end of the first tracer pattern 1175a and does not overlap the second semiconductor chip 130 in a plan view, and a second bonding pad 1177a which is formed at the other end opposite to the one end of the first tracer pattern 1175a and overlaps the second semiconductor chip 130.

The second horizontal redistribution structure 117b includes a second tracer pattern 1175b extending at the second angle θ2 from the second horizontal direction (Y direction), a first bonding pad 1173b which is formed at one end of the second tracer pattern 1175b and does not overlap the second semiconductor chip 130 in a plan view, and a second bonding pad 1177b which is formed at the other end opposite to the one end of the second tracer pattern 1175b and overlaps the second semiconductor chip 130.

The third horizontal redistribution structure 117c includes a third tracer pattern 1175c extending at a third angle θ3 from the second horizontal direction (Y direction), a first bonding pad 1173c which is formed at one end of the third tracer pattern 1175c and does not overlap the second semiconductor chip 130 in a plan view, and a second bonding pad 1177c which is formed at the other end opposite to the one end of the third tracer pattern 1175c and overlaps the second semiconductor chip 130.

The fourth horizontal redistribution structure 117d includes a fourth tracer pattern 1175d extending at a fourth angle θ4 from the second horizontal direction (Y direction), a first bonding pad 1173d which is formed at one end of the fourth tracer pattern 1175d and overlaps the second semiconductor chip 130 in a plan view, and a second bonding pad 1177d which is formed at the other end opposite to the one end of the fourth tracer pattern 1175d and overlaps the second semiconductor chip 130. Since the fourth horizontal redistribution structure 117d is positioned close to the inside of the second semiconductor chip 130 rather than the outside in a plan view, the first bonding pad 1173d of the fourth horizontal redistribution structure 117d and the second bonding pad 1177d of the fourth horizontal redistribution structure 117d may each overlap the second semiconductor chip 130.

According to an embodiment, the vertical redistribution structures 115 and the horizontal redistribution structures 117 may include at least one of Ti, Ta, Al, Au, Cu, Ni, W, TiN, or TaN.

According to an embodiment, the semiconductor package 10 may be redistributed with the single-layered horizontal redistribution structures 117 even without a plurality of conductive patterns and a plurality of conductive vias, thereby reducing process costs. In addition, since the redistribution structure 110 includes only a single-layered insulating layer, warpage may be easily controlled.

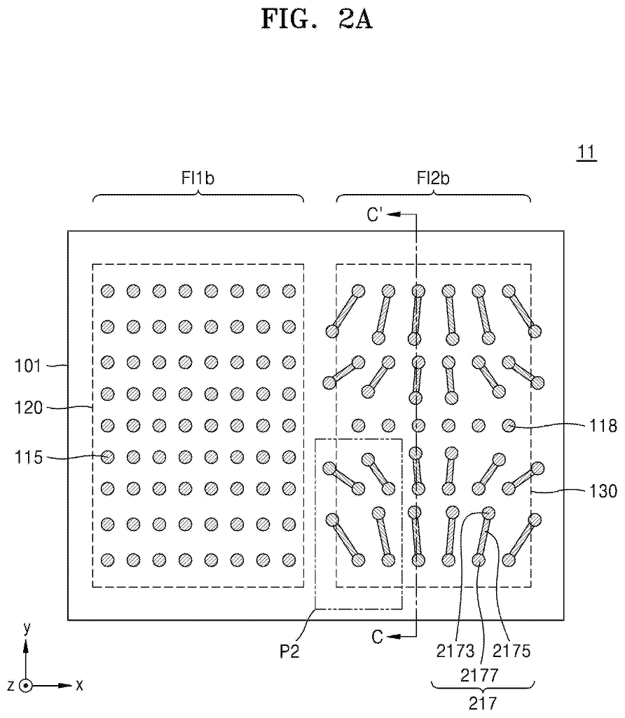

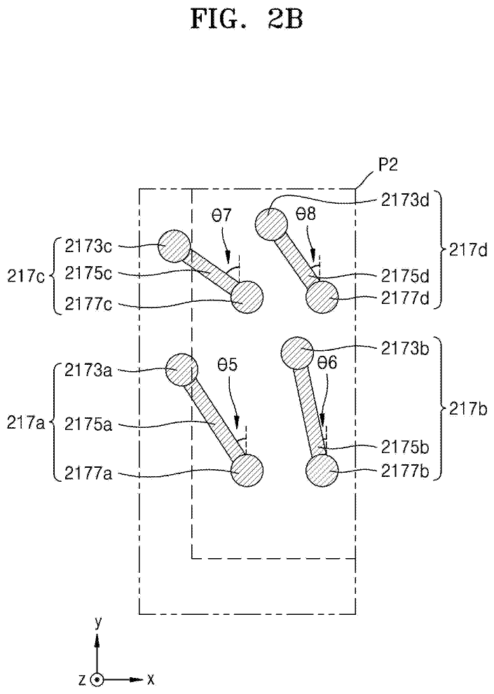

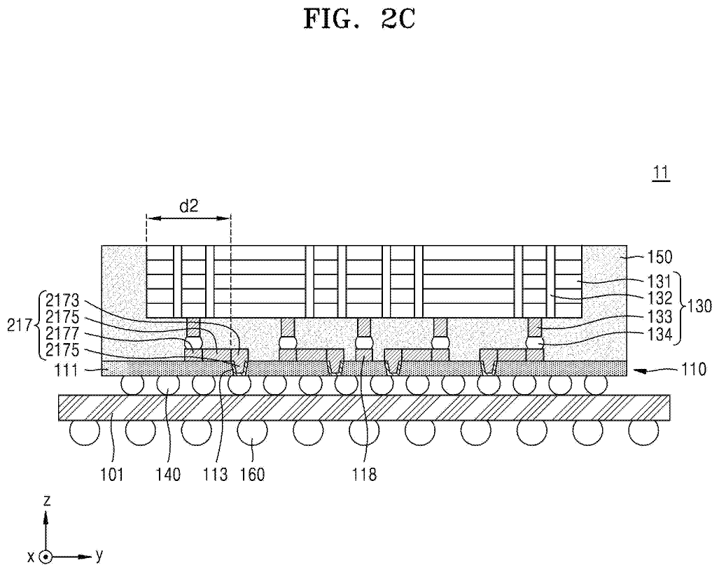

FIG. 2A is a plan view of a redistribution structure of a semiconductor package according to an embodiment. FIG. 2B is an enlarged view of a portion P2 of FIG. 2A, and FIG. 2C is a cross-sectional view taken along a line C-C′ of FIG. 2A.

Referring to FIGS. 2A to 2C, a semiconductor package 11 shown in FIGS. 2A to 2C is substantially the same as or similar to the semiconductor package 10 shown in FIGS. 1A to 1D except that the arrangement of a plurality of horizontal redistribution structures 217 is different from that of the plurality of horizontal redistribution structures 117 shown in FIGS. 1A to 1D. Therefore, a description of the components already mentioned with reference to FIGS. 1A to 1D is omitted.

As shown in FIG. 2C, a first bonding pad 2173 of the horizontal redistribution structure 217 may be located closer to the center of the second semiconductor chip 130 than a second bonding pad 2177. A distance from an edge of the second semiconductor chip 130 to the first bonding pad 2173 of the horizontal redistribution structure 217 may be distance d2. In a plan view, the first bonding pad 1173 of the horizontal redistribution structure 117 may be inside the second semiconductor chip 130. As such, the second semiconductor chip 130 may overlap the first bonding pad 1173 of the horizontal redistribution structure 117. According to an embodiment, a fifth angle θ5 of a first horizontal redistribution structure 217a inclined with respect to the second horizontal direction (Y direction) may be different from a sixth angle θ6 of a second horizontal redistribution structure 217b inclined with respect to the second horizontal direction (Y direction). As shown in FIG. 2B, since the first horizontal redistribution structure 217a is positioned further outside the second semiconductor chip 130 in a plan view than the second horizontal redistribution structure 217b, the fifth angle θ5 may be greater than the sixth angle θ6. However, the fifth angle θ5 is not necessarily limited thereto and may be less than the sixth angle θ6 according to an embodiment.

The first horizontal redistribution structure 217a includes a first tracer pattern 2175a extending at the fifth angle θ5 from the second horizontal direction (Y direction), a first bonding pad 2173a which is formed at one end of the first tracer pattern 2175a and partially overlaps the second semiconductor chip 130 in a plan view, and a second bonding pad 2177a which is formed at the other end opposite to the one end of the first tracer pattern 2175a and overlaps the second semiconductor chip 130. However, according to an embodiment, the first tracer pattern 2175a may not completely overlap the second semiconductor chip 130 in a plan view.

The second horizontal redistribution structure 217b includes a second tracer pattern 2175b extending at the sixth angle θ6 from the second horizontal direction (Y direction), a first bonding pad 2173b which is formed at one end of the second tracer pattern 2175b and overlaps the second semiconductor chip 130 in a plan view, and a second bonding pad 2177b which is formed at the other end opposite to the one end of the second tracer pattern 2175b and overlaps the second semiconductor chip 130.

The third horizontal redistribution structure 217c includes a third tracer pattern 2175c extending at a seventh angle θ7 from the second horizontal direction (Y direction), a first bonding pad 2173c which is formed at one end of the third tracer pattern 1175c and does not overlap the second semiconductor chip 130 in a plan view, and a second bonding pad 2177c which is formed at the other end opposite to the one end of the third tracer pattern 2175c and overlaps the second semiconductor chip 130.

The fourth horizontal redistribution structure 217d includes a fourth tracer pattern 2175d extending at an eighth angle θ8 from the second horizontal direction (Y direction), a first bonding pad 2173d which is formed at one end of the fourth tracer pattern 2175d and overlaps the second semiconductor chip 130 in a plan view, and a second bonding pad 2177d which is formed at the other end opposite to the one end of the fourth tracer pattern 2175d and overlaps the second semiconductor chip 130. Since the fourth horizontal redistribution structure 217d is positioned close to the inside of the second semiconductor chip 130 rather than the outside in a plan view, the first bonding pad 2173d of the fourth horizontal redistribution structure 217d and the second bonding pad 2177d of the fourth horizontal redistribution structure 217d may each overlap the second semiconductor chip 130. Compared with the plurality of first bonding pads 1173a, 1173b, 1173c, and 1173d of the semiconductor package 11 shown in FIGS. 1A to 1D, a larger number of first bonding pads 2173a, 2173b, 2173c, and 2173d shown in FIGS. 2A to 2C may overlap the second semiconductor chip 130. Moreover, the distance d2 from an edge of the second semiconductor chip 130 to the first bonding pad 2173 of the horizontal redistribution structure 217 may be greater than the distance d1 from an edge of the second semiconductor chip 130 to the first bonding pad 2173 of the horizontal redistribution structure 117.

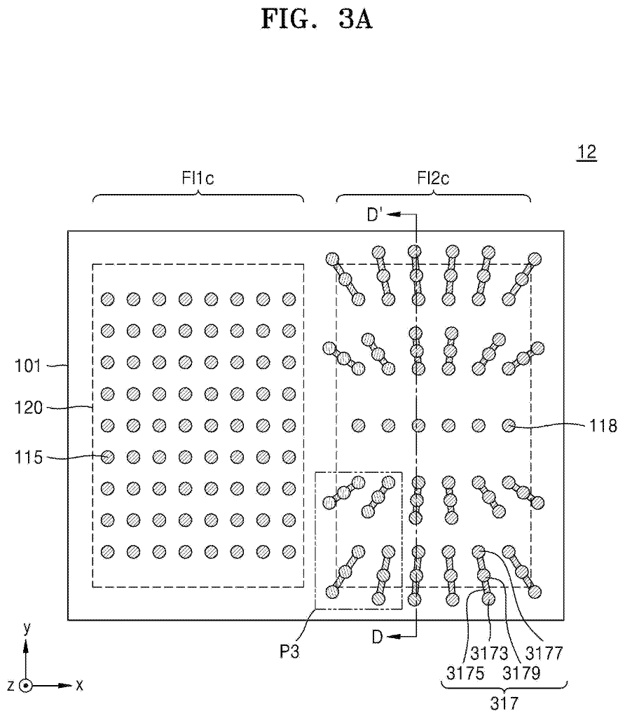

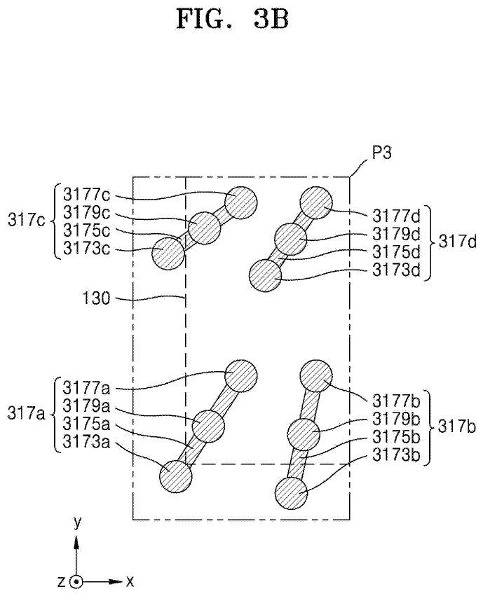

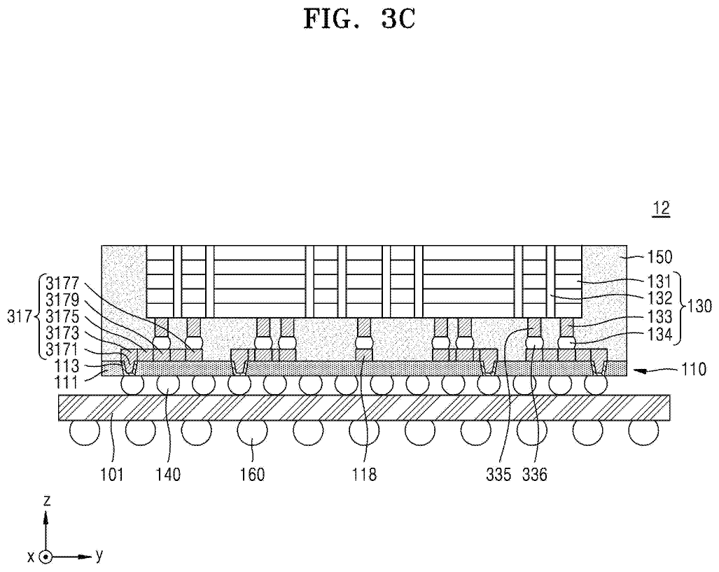

FIG. 3A is a plan view of a redistribution structure of a semiconductor package according to an embodiment. FIG. 3B is an enlarged view of a portion P3 of FIG. 3A, and FIG. 3C is a cross-sectional view taken along a line D-D′ of FIG. 3A.

Referring to FIGS. 3A to 3C, a semiconductor package 12 shown in FIGS. 3A to 3C is substantially the same as or similar to the semiconductor package 10 shown in FIGS. 1A to 1D except that each of a plurality of horizontal redistribution structures 317 further include a third bonding pad 3179, and the second semiconductor chip 130 further includes dummy vertical connection conductors 335 and dummy chip connection terminals 336. Therefore, a description of the components already mentioned with reference to FIGS. 1A to 1D is omitted.

Referring to FIGS. 3A to 3C, the plurality of horizontal redistribution structures 317a, 317b, 317c, and 317d may further include third bonding pads 3179a, 3179b, 3179c, and 3179d formed on tracer patterns 3175a, 3175b, 3175c, and 3175d between first bonding pads 3173a, 3173b, 3173c, and 3173d and second bonding pads 3177a, 3177b, 3177c, and 3177d, respectively. In addition, the second semiconductor chip 130 may further include the dummy vertical connection conductors 335 provided on a lowermost chip among the plurality of chips 131, the dummy chip connection terminals 336 may be connected to the dummy vertical connection conductors 335, and the third bonding pads 3179a, 3179b, 3179c, and 3179d may be bonded to the dummy chip connection terminals 336. For example, the dummy chip connection terminals 336 may be physical connected or bonded to the dummy vertical connection conductors 335, and the third bonding pads 3179a, 3179b, 3179c, and 3179d may be physically connected or bonded to the dummy chip connection terminals 336 As the second semiconductor chip 130 further includes the dummy vertical connection conductors 335 and the dummy chip connection terminals 336, the heat dissipation effect of the second semiconductor chip 130 may increase.

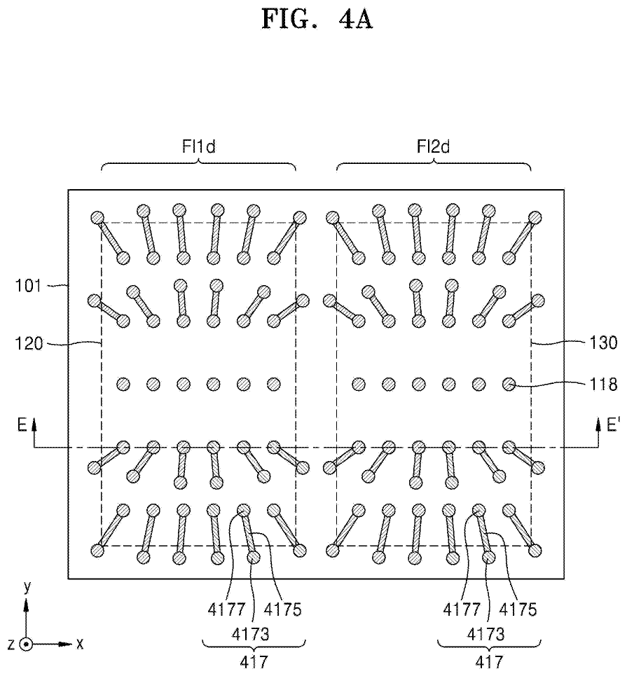

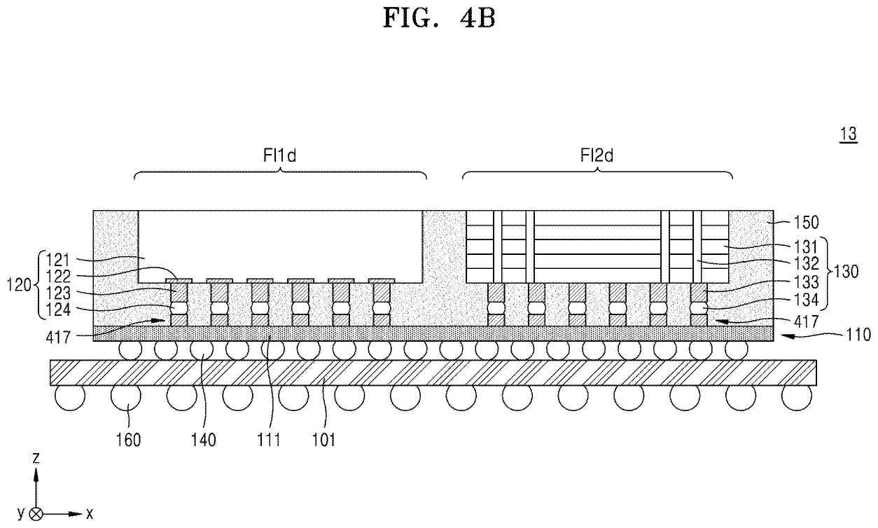

FIG. 4A is a plan view of a redistribution structure of a semiconductor package according to an embodiment, and FIG. 4B is a cross-sectional view taken along a line E-E′ of FIG. 4A.

Referring to FIGS. 4A and 4B, a semiconductor package 13 shown in FIGS. 4A and 4B is substantially the same as or similar to the semiconductor package 10 shown in FIGS. 1A to 1D except that a plurality of horizontal redistribution structures 417 are also arranged in a first fan-in area FI1d. Therefore, a description of the components already mentioned with reference to FIGS. 1A to 1D is omitted.

In the first fan-in area FI1d, the plurality of horizontal redistribution structures 417 may be arranged side-by-side in the first horizontal direction (X direction) and the second horizontal direction (Y direction). Each of the plurality of horizontal redistribution structures 417 may include a tracer pattern 4175 extending from the second horizontal direction (Y direction), a first bonding pad 4173 formed at one end of the tracer pattern 4175, and a second bonding pad 4177 formed at the other end opposite to the one end of the tracer pattern 4175 and bonded to the second chip connection terminal 134. The plurality of horizontal redistribution structures 417 arranged in the first fan-in area FI1d may be substantially the same as the plurality of horizontal redistribution structures 417 arranged in the second fan-in area FI2d.

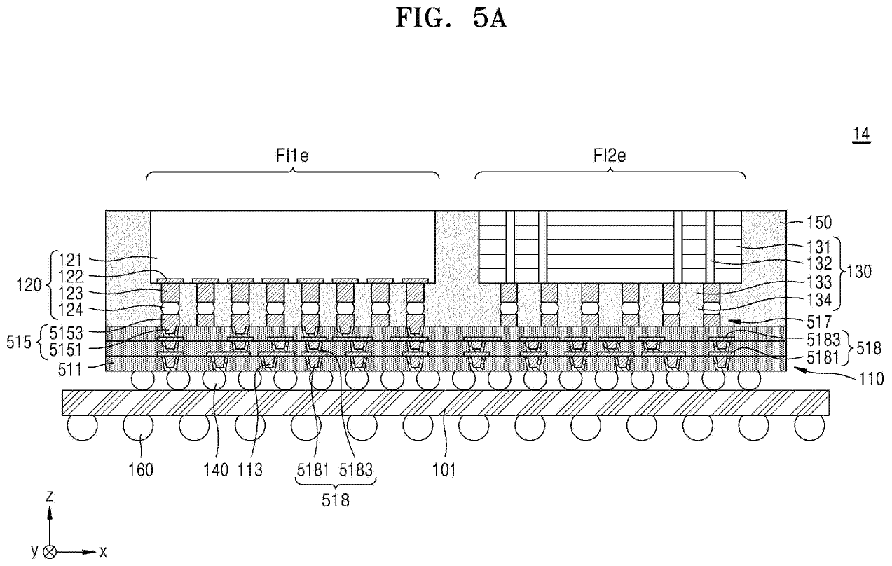

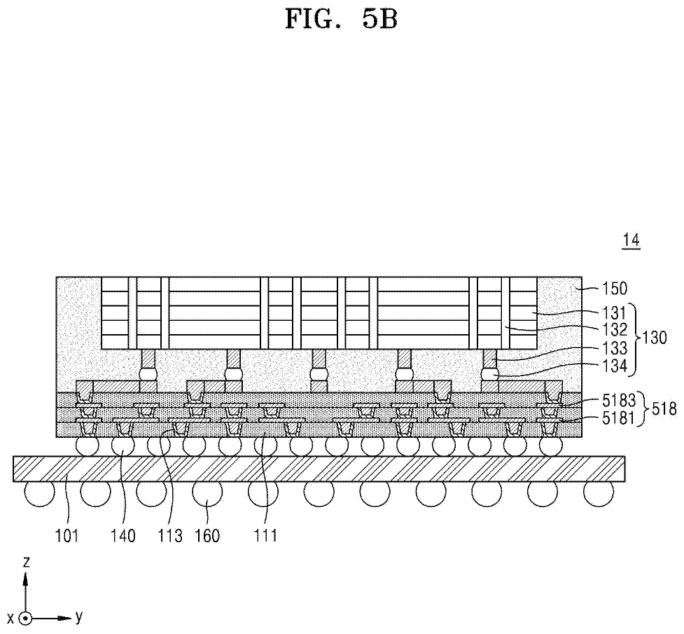

FIGS. 5A and 5B are cross-sectional views of a semiconductor package according to an embodiment. FIG. 5A is a cross-sectional view corresponding to FIG. 1C, and FIG. 5B is a cross-sectional view corresponding to FIG. 1D.

Referring to FIGS. 5A and 5B, a semiconductor package 14 shown in FIGS. 5A and 5B is substantially the same as or similar to the semiconductor package 10 shown in FIGS. 1A to 1D except that a plurality of insulating layers 511 and a plurality of conductive redistribution patterns 518 are formed below the plurality of horizontal redistribution structures 517 and the plurality of vertical redistribution structures 515. Therefore, a description of the components already mentioned with reference to FIGS. 1A to 1D is omitted.

The semiconductor package 14 may include the plurality of insulating layers 511 and the plurality of conductive redistribution patterns 518. Each of the plurality of vertical redistribution structures 515 may include vertical redistribution vias 5151 and vertical redistribution pads 5153. Each of the plurality of conductive redistribution patterns 518 may include a conductive via pattern 5181 and a conductive layer 5183.

The conductive layers 5183 may extend in the first horizontal direction (X direction) and the second horizontal direction (Y direction) and may be arranged at different vertical levels to form a multilayer structure. The conductive layers 5183 may be arranged on any one of an upper surface and a lower surface of each of the plurality of insulating layers 511. For example, the conductive layers 5183 may include a line pattern extending in a line shape along one of the upper and lower surfaces of any one of the plurality of insulating layers 511. The conductive via patterns 5181 may extend in the vertical direction (Z direction) through at least one of the plurality of insulating layers 511. The conductive via patterns 5181 may electrically connect the conductive layers 5183 arranged at different vertical levels or electrically connect the conductive layers 5183 to the first external connection terminals 140. For example, the conductive layers 5183 and the conductive via patterns 5181 may include metals such as Cu, Al, W, Ti, Ta, In, molybdenum (Mo), manganese (Mn), cobalt (Co), tin (Sn), Ni, magnesium (Mg), rhenium (Re), beryllium (Be), Ga, ruthenium (Ru), or alloys thereof.

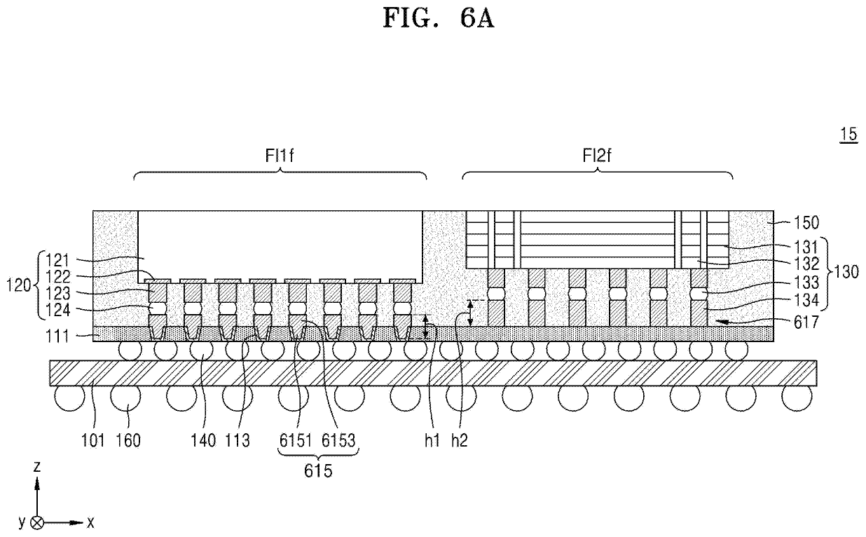

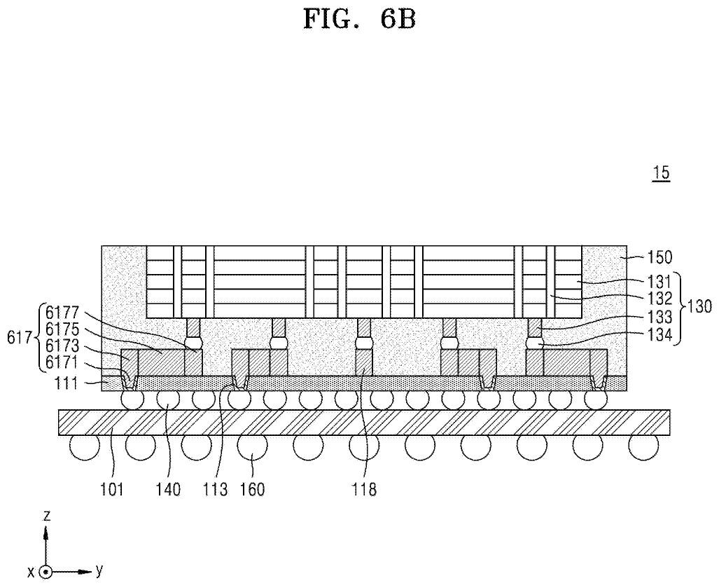

FIGS. 6A and 6B are cross-sectional views of a semiconductor package according to an embodiment. FIG. 6A is a cross-sectional view corresponding to FIG. 1C, and FIG. 6B is a cross-sectional view corresponding to FIG. 1D.

Referring to FIGS. 6A and 6B, a semiconductor package 15 shown in FIGS. 6A and 6B is substantially the same as or similar to the semiconductor package 10 shown in FIGS. 1A to 1D except that a length of a plurality of horizontal redistribution structures 617 is different from that of a plurality of vertical redistribution structures 615, in the vertical direction (Z direction). Therefore, a description of the components already mentioned with reference to FIGS. 1A to 1D is omitted.

As shown in FIG. 6A, a length h1 of the plurality of vertical redistribution structures 615 in the vertical direction (Z direction) is longer than a length h2 of the plurality of horizontal redistribution structures 617 in the vertical direction (z direction). However, the length h2 of the plurality of horizontal redistribution structures 617 in the vertical direction (Z direction) is not limited thereto and may be longer than the length h1 of the plurality of vertical redistribution structures 615 in the vertical direction (z direction), according to an embodiment. As such, when the length of the plurality of vertical redistribution structures 615 in the vertical direction (Z direction) is different from that of the plurality of horizontal redistribution structures 617 in the vertical direction (Z direction), it is easy to adjust the length of the first and second semiconductor chips 120 and 130 in the vertical direction (Z direction). Each of the plurality of vertical redistribution structures 615 may include vertical redistribution vias 6151 and vertical redistribution pads 6153.

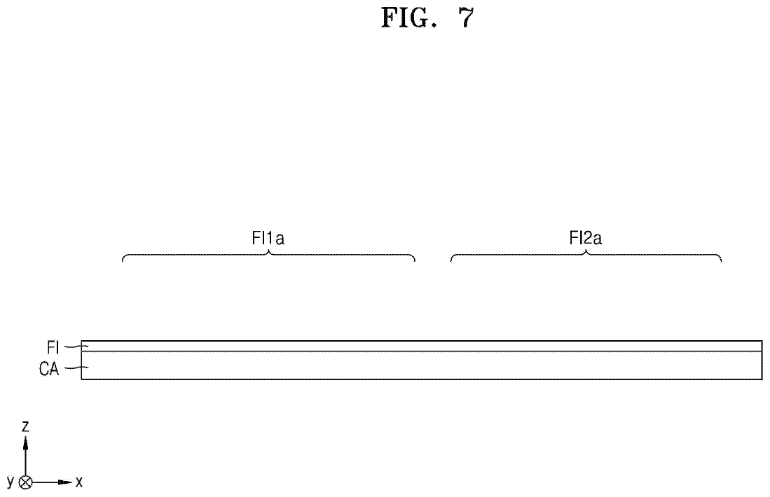

FIGS. 7 to 16 are cross-sectional views sequentially illustrating a method of manufacturing a semiconductor package, according to an embodiment.

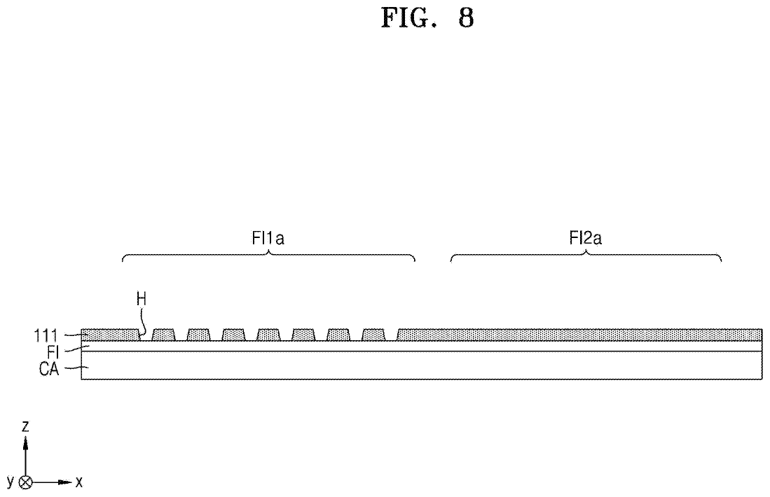

Referring to FIG. 7, the method of manufacturing a semiconductor package according to an embodiment may include attaching an adhesive film FI to a carrier substrate CA. The adhesive film FI may include any material capable of fixing the insulating layer 111 (see FIG. 8) and the like. The adhesive film FI may include, but is not limited to, a heat curable adhesive tape having adhesive strength that is weakened by heat treatment, or an ultraviolet curable adhesive tape having adhesive strength that is weakened by UV irradiation.

Referring to FIG. 8, the method of manufacturing a semiconductor package according to an embodiment may include forming the insulating layer 111 on the adhesive film FI and patterning the insulating layer 111 to form a plurality of holes H. The plurality of holes H may be spaces subsequently filled with conductive material to form vertical redistribution structures or horizontal redistribution structures. The holes H in the insulating layer 111 in the first fan-in area FI1a may be spaces in which the vertical redistribution vias 1151 (see FIG. 1C) are to be formed, and the holes H in the insulating layer 111 in the second fan-in area FI2a may be spaces in which the horizontal redistribution vias 1171 (see FIG. 1D) are to be formed.

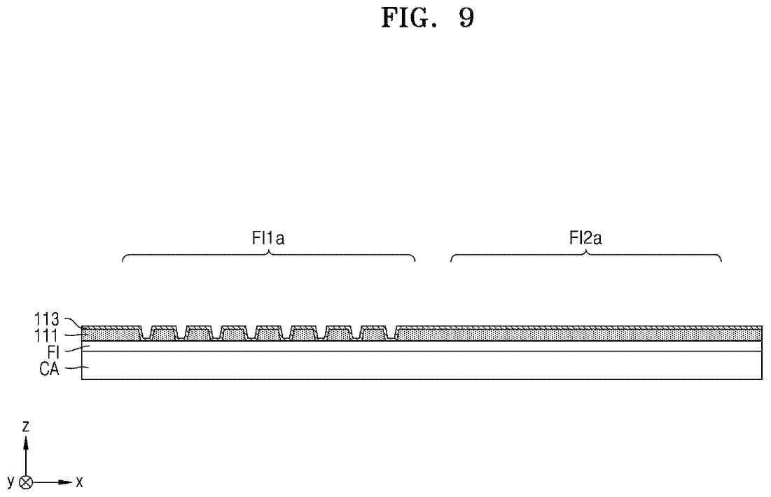

Referring to FIG. 9, the method of manufacturing a semiconductor package according to an embodiment may include applying the seed layer 113 to the insulating layer 111 and the plurality of holes H to cover the plurality of holes H. The seed layer 113 may be provided on the plurality of holes H and the upper surface of the insulating layer 111. The seed layer 113 may conformally cover the plurality of holes H and the upper surface of the insulating layer 111. A process of forming the seed layer 113 may be performed by an atomic layer deposition (ALD) method, a chemical vapor deposition (CVD) method, or a physical vapor deposition (PVD) method. Alternatively, the seed layer 113 may be formed by a sputtering process.

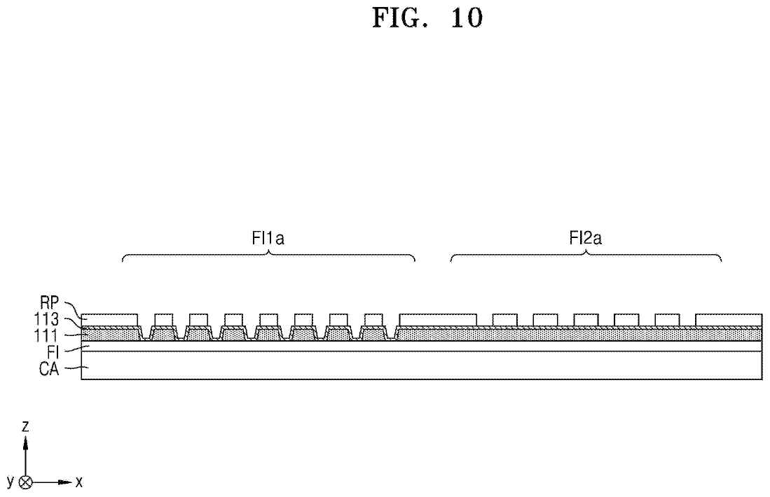

Referring to FIG. 10, the method of manufacturing a semiconductor package according to an embodiment may include forming a plurality of reference patterns RP between the plurality of holes H on the insulating layer 111. The plurality of reference patterns RP may function as a frame into which metal material may be subsequently filled.

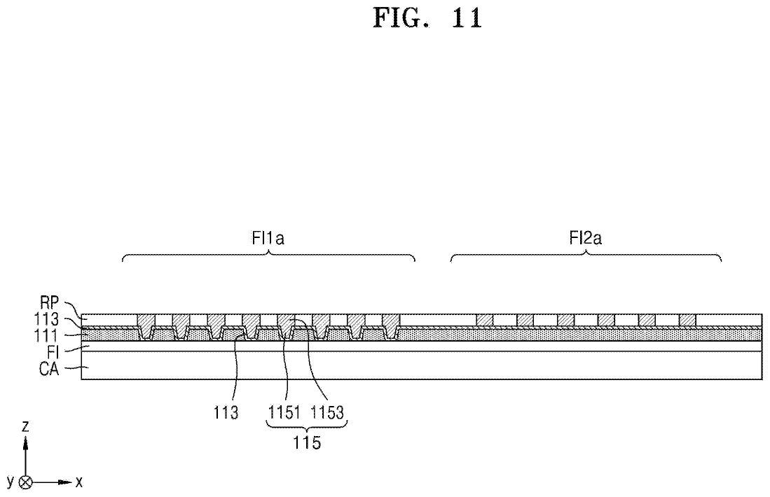

Referring to FIG. 11, the method of manufacturing a semiconductor package according to an embodiment may include filling spaces between the plurality of reference patterns RP and the plurality of holes H with metal material to form the plurality of horizontal redistribution structures 117 and the plurality of vertical redistribution structures 115. A process of forming the plurality of horizontal redistribution structures 117 and the plurality of vertical redistribution structures 115 may be performed by a plating process.

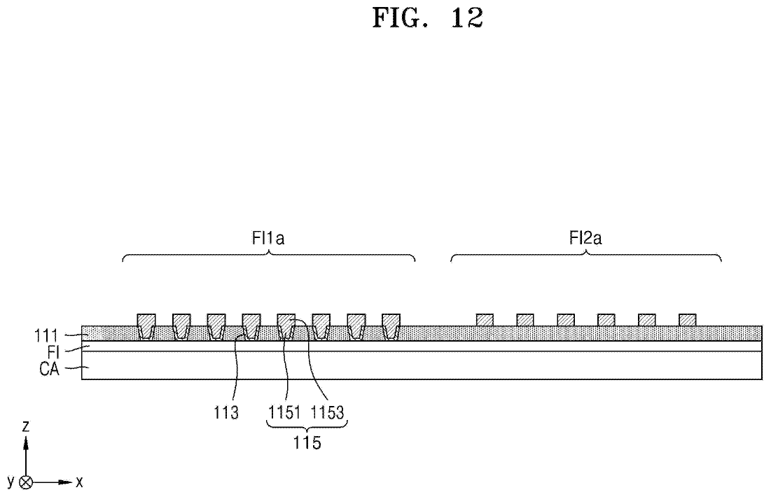

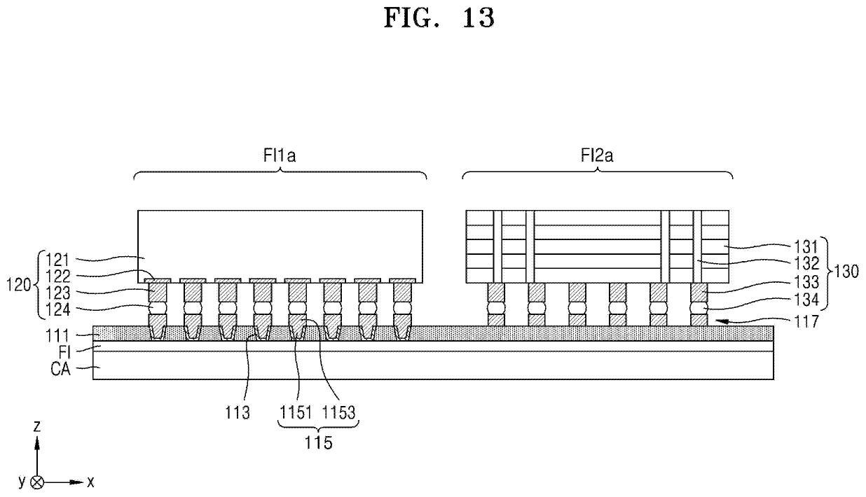

Referring to FIGS. 12 and 13, the method of manufacturing a semiconductor package according to an embodiment may include after removing the plurality of reference patterns RP, mounting the first semiconductor chip 120 and the second semiconductor chip 130 on the redistribution structure 110. To mount the first semiconductor chip 120 and the second semiconductor chip 130 on the on the redistribution structure 110, the first chip connection terminals 124 of the first semiconductor chip 120 may be bonded to the plurality of vertical redistribution structures 115, and the second chip connection terminals 134 of the second semiconductor chip 130 may be respectively bonded to the plurality of horizontal redistribution structures 117.

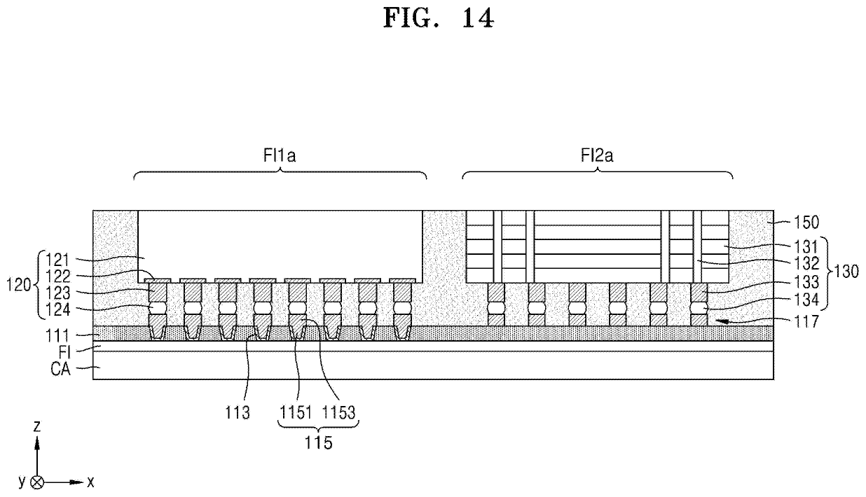

Referring to FIG. 14, the method of manufacturing a semiconductor package according to an embodiment may include forming the molding layer 150 sealing the first semiconductor chip 120 and the second semiconductor chip 130 on the redistribution structure 110. An upper surface of the molding layer 150 may be positioned on the same plane as an upper surface of the first semiconductor chip 120 and an upper surface of the second semiconductor chip 130.

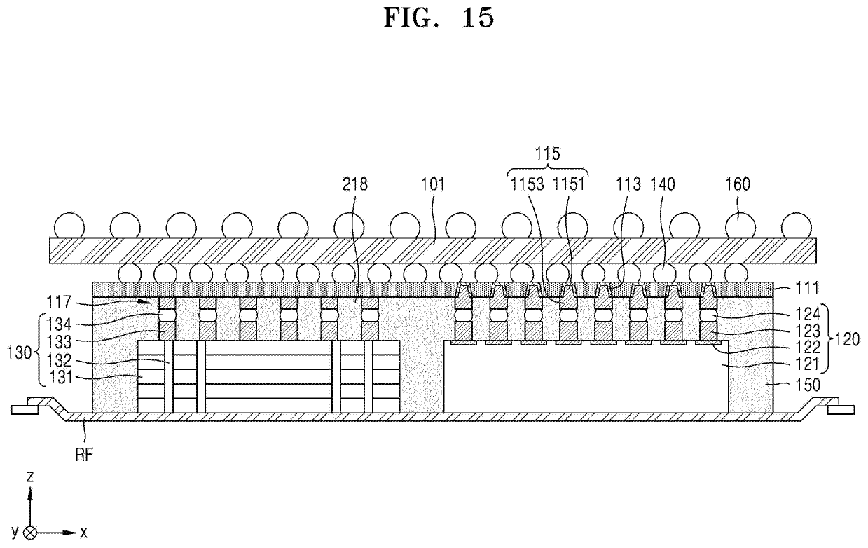

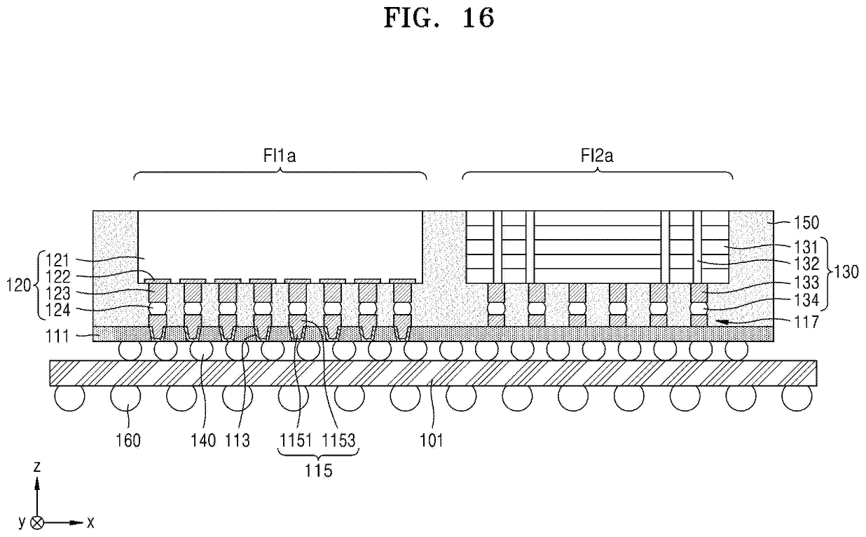

Referring to FIGS. 15 and 16, in the method of manufacturing a semiconductor package according to an embodiment, after the carrier substrate CA and the adhesive film FI are removed from the redistribution structure 110, a ring frame RF may be attached to the upper surfaces of the first and second semiconductor chips 120 and 130 and the upper surface of the molding layer 150. One side of the ring frame RF may be coated with adhesive material to adhere to the upper surfaces of the first and second semiconductor chips 120 and 130 and a portion of the upper surface of the molding layer 150. After the ring frame RF is attached to the upper surfaces of the first and second semiconductor chips 120 and 130 and the upper surface of the molding layer 150, the ring frame RF may be turned upside down so that the lower surface of the redistribution structure 110 faces the vertical direction (Z direction). Subsequently, the first external connection terminals 140 physically and electrically connected to the vertical redistribution vias 1151 and the horizontal redistribution vias 1171 of the horizontal redistribution structures 117 are attached to the lower surface of the redistribution structure 110. Subsequently, the package substrate 101 coupled to the second external connection terminal 160 may be attached to the first external connection terminal 140.

Referring to FIG. 16, the method of manufacturing a semiconductor package according to an embodiment may further include turning the ring frame RF upside down, so that the upper surfaces of the first and second semiconductor chips 120 and 130 face the vertical direction (Z direction). Subsequently, the ring frame RF may be removed from the upper surfaces of the first and second semiconductor chips 120 and 130 to complete the semiconductor package 10.

While the disclosure has been particularly shown and described with reference to embodiments thereof, it will be understood that various changes in form and details may be made therein without departing from the spirit and scope of the following claims.

1. A semiconductor package comprising:
a package substrate;
a redistribution structure comprising:
an insulating layer provided on a first side of the package substrate, and
a plurality of horizontal redistribution structures provided in the insulating layer and arranged adjacent to each other in a first horizontal direction and a second horizontal direction, the first and the second horizontal directions parallel to an upper surface of the package substrate and the second horizontal direction perpendicular to the first horizontal direction;
external connection terminals provided on a first side of the redistribution structure; and
a semiconductor chip provided on the redistribution structure, the semiconductor chip comprising a chip body and chip connection terminals provided on a first side of the chip body;
wherein each of the plurality of horizontal redistribution structures comprises:
a via through the insulating layer;
a tracer pattern formed integrally with the via and extending at an angle from the first horizontal direction and the second horizontal direction;
a first bonding pad provided on the insulating layer, integrally formed with the via, and formed at a first position on the tracer pattern; and
a second bonding pad formed at a second position on the tracer pattern different from the first position and bonded to the chip connection terminal.

2. The semiconductor package of claim 1,
wherein the plurality of horizontal redistribution structures comprises:
a first horizontal redistribution structure overlapping a vertex of the semiconductor chip in a plan view, and
a second horizontal redistribution structure spaced apart from the first horizontal redistribution structure in the first horizontal direction,
wherein the first horizontal redistribution structure and the second horizontal redistribution structure are arranged on a first side with respect to a centerline crossing the center of the semiconductor package in the second horizontal direction.

3. The semiconductor package of claim 2,
wherein a first angle at which the first horizontal redistribution structure extends with respect to the second horizontal direction is different from a second angle at which the second horizontal redistribution structure with respect to the second horizontal direction.

4. The semiconductor package of claim 1,
wherein the first bonding pad does not overlap the semiconductor chip in a vertical direction, and
wherein the second bonding pad completely overlaps the semiconductor chip in the vertical direction.

5. The semiconductor package of claim 1,
wherein a first height of the first bonding pad in a vertical direction and a second height of the second bonding pad in the vertical direction is same as a third height of the tracer pattern in the vertical direction.

6. The semiconductor package of claim 1,
wherein the plurality of horizontal redistribution structures are arranged symmetrically with respect to a centerline crossing the center of the semiconductor chip in the first horizontal direction and
a centerline crossing the center of the semiconductor chip in the second horizontal direction.

7. The semiconductor package of claim 1,
wherein the first bonding pad is positioned farther from the center of the semiconductor chip than the second bonding pad.

8. The semiconductor package of claim 1,
wherein the first bonding pad is positioned closer to the center of the semiconductor chip than the second bonding pad.

9. The semiconductor package of claim 1,
wherein the second bonding pad has a circular column shape, and
a length of the second bonding pad in a vertical direction is longer than a diameter of the second bonding pad.

10. The semiconductor package of claim 1,
wherein the horizontal redistribution structure further comprises a third bonding pad formed on the tracer pattern between the first bonding pad and the second bonding pad,
wherein the semiconductor chip further comprises a dummy chip connection terminal provided on a side of the chip body, and
wherein the third bonding pad is bonded to the dummy chip connection terminal.

11. A semiconductor package comprising:
a package substrate;
a redistribution structure comprising:
an insulating layer provided on a first side of the package substrate,
a plurality of horizontal redistribution structures provided in the insulating layer and arranged adjacent to each other in a first horizontal direction and in a second horizontal direction perpendicular to the first horizontal direction, and
a plurality of vertical redistribution structures;
external connection terminals provided on a first side of the redistribution structure;
a first semiconductor chip provided on the redistribution structure, the semiconductor chip comprising a first chip body and first chip connection terminals provided on a first side of the first chip body; and
a second semiconductor chip spaced apart from the first semiconductor chip in the first horizontal direction and comprising a second chip body and second chip connection terminals provided on a first side of the second chip body;
wherein the plurality of vertical redistribution structures completely overlap the first semiconductor chip in a vertical direction,
wherein each of the plurality of horizontal redistribution structures comprises:
a via through the insulating layer;
a tracer pattern formed integrally with the via and extending at an angle from the first horizontal direction and the second horizontal direction;
a first bonding pad provided on the insulating layer, integrally formed with the via, and formed at a first position on the tracer pattern; and
a second bonding pad formed at a second position on the tracer pattern different from the first position and bonded to the second chip connection terminal.

12. The semiconductor package of claim 11,
wherein the first semiconductor chip comprises a logic semiconductor chip, and
wherein the second semiconductor chip comprises a high bandwidth memory (HBM) chip.

13. The semiconductor package of claim 11,
wherein each of the plurality of vertical redistribution structures comprises:
a vertical redistribution via through the insulating layer; and
a vertical redistribution pad integrally formed with an upper portion of the vertical redistribution via and bonded to the first chip connection terminal.

14. The semiconductor package of claim 13,
wherein a first length of the second bonding pad in the vertical direction is longer than a second length of the vertical redistribution pad in the vertical direction.

15. The semiconductor package of claim 11,
wherein the second bonding pad has a circular column shape, and
a length of the second bonding pad in the vertical direction is longer than a diameter of the second bonding pad.

16. The semiconductor package of claim 11,
wherein the plurality of horizontal redistribution structures further comprise:
a first horizontal redistribution structure overlapping a vertex of the second semiconductor chip in a plan view; and
a second horizontal redistribution structure spaced apart from the first horizontal redistribution structure in the first horizontal direction,
wherein the first horizontal redistribution structure and the second horizontal redistribution structure are arranged on a first side with respect to a centerline crossing the center of the second semiconductor chip in the second horizontal direction, and
an inclined angle of the first horizontal redistribution structure with respect to the second horizontal direction is different from an inclined angle of the second horizontal redistribution structure with respect to the second horizontal direction.

17. The semiconductor package of claim 16,
wherein the plurality of horizontal redistribution structures further comprise:
a third horizontal redistribution structure spaced from the first horizontal redistribution structure in the second horizontal direction,
wherein the first horizontal redistribution structure and the third horizontal redistribution structure are arranged on a second side respect to a centerline crossing the center of the second semiconductor chip in the first horizontal direction, and
the inclined angle of the first horizontal redistribution structure with respect to the second horizontal direction is different from an inclined angle of the third horizontal redistribution structure with respect to the second horizontal direction.

18. The semiconductor package of claim 11,
wherein the first bonding pad does not overlap the second semiconductor chip in the vertical direction, and
wherein the second bonding pad completely overlaps the second semiconductor chip in the vertical direction.

19. A semiconductor package comprising a package substrate;
a redistribution structure comprising:
an insulating layer provided on a first side the package substrate,
a plurality of horizontal redistribution structures provided in the insulating layer and arranged side-by-side in a first horizontal direction and in a second horizontal direction perpendicular to the first horizontal direction, and
a plurality of vertical redistribution structures;
external connection terminals arranged below the redistribution structure;
a first semiconductor chip provided on the redistribution structure, the semiconductor chip comprising a first chip body and first chip connection terminals arranged on a first side of the first chip body; and
a second semiconductor chip spaced apart from the first semiconductor chip in the first horizontal direction and comprising a second chip body and second chip connection terminals arranged on a first side of the second chip body;
wherein the plurality of horizontal redistribution structures further comprise:
a first horizontal redistribution structure overlapping a vertex of the second semiconductor chip in a plan view and extend in a first angle with respect to the second horizontal direction;
a second horizontal redistribution structure spaced apart from the first horizontal redistribution structure in the first horizontal direction and extend in a second angle different from the first angle with respect to the second horizontal direction; and
a third horizontal redistribution structure spaced apart from the first horizontal redistribution structure in the second horizontal direction and extend in a third angle different from the first angle with respect to the second horizontal direction,
wherein the plurality of vertical redistribution structures completely overlap the first semiconductor chip in a vertical direction.

20. The semiconductor package of claim 19,
wherein each of the plurality of horizontal redistribution structures comprises:
a via through the insulating layer;
a tracer pattern formed integrally with the via and extend from the first horizontal direction and the second horizontal direction;
a first bonding pad provided on the insulating layer, integrally formed with the via, and formed at a first position of the tracer pattern; and
a second bonding pad formed at a second position of the tracer pattern and bonded to the second chip connection terminal.

21-25. (canceled)
